(19) United States
(12) Patent Application Publication
(10) Pub. No.: US 2018/0059937 A1
(43) Pub. Date: Mar. 1, 2018

(54) MEMORY SYSTEM AND OPERATING METHOD THEREOF

(71) Applicant: SK hynix Inc., Gyeonggi-do (KR)

(72) Inventor: Jee-Yul KIM, Gyeonggi-do (KR)

(21) Appl. No.: 15/461,606

(22) Filed: Mar. 17, 2017

(30) Foreign Application Priority Data
Aug. 25, 2016 (KR) 10-2016-0108302

(51) Int. Cl. G06F 3/06; G11C 16/10; G06F 12/02; G06F 11/10; G11C 29/52

(52) U.S. Cl. CPC G06F 3/061; G11C 16/10; G06F 3/0619; G06F 3/065; G06F 3/0652; G06F 3/0679; G06F 2212/7201; G06F 11/1068; G11C 29/52; G06F 2212/1016; G06F 2212/1032; G06F 2212/214; G06F 12/0246

(57) ABSTRACT

A memory system comprises a memory device including a normal cell region and a redundancy cell region, and a controller suitable for programming data in duplicate in both the normal and the redundancy cell regions, wherein when detecting an error in the data read from the normal cell region, the controller invalidates the data of the normal cell region and validates the data of the redundancy cell region.

### CROSS-REFERENCE TO RELATED APPLICATION

The present application claims priority under 35 U.S.C. §119(a) to Korean Patent Application No. 10-2016-0108302 filed on Aug. 25, 2016 in the Korean Intellectual Property Office, the disclosure of which is incorporated herein by reference in its entirety.

### TECHNICAL FIELD

Exemplary embodiments relate generally to a memory system, and more particularly, to a memory system including a memory device with normal and redundancy cell regions, and an operating method thereof.

### DISCUSSION OF THE RELATED ART

The computer environment paradigm has shifted to ubiquitous computing systems that can be used anytime and anywhere. Due to this, use of portable electronic devices such as mobile phones, digital cameras, and notebook computers has rapidly increased. These portable electronic devices generally use a memory system having one or more memory devices, for data storage. The memory system may be used as a main memory or an auxiliary memory of a portable electronic device.

Memory systems provide excellent stability, durability, high information access speed, and low power consumption, since they have no moving parts. Examples of memory systems having such advantages include universal serial bus (USB) memory devices, memory cards having various interfaces, and solid state drives (SSD).

### SUMMARY

Various embodiments of the present invention are directed to a memory system capable of programming the same data in duplicate into both a normal and a redundancy memory location in corresponding normal cell and redundancy cell regions of a memory device and of substituting the normal and redundancy memory locations in order to prevent data error corruption. Various embodiments of the present invention are directed to a method of operating the memory system. The memory system and method thereof can reduce data error corruption while at the same time improving the speed, reliability and efficiency of data operations.

In accordance with an embodiment of the present invention, a memory system includes: a memory device including a normal cell region and a redundancy cell region; and a controller suitable for programming data in duplicate in both the normal and the redundancy cell regions, wherein when detecting an error in the data read from the normal cell region, the controller invalidates the data of the normal cell region and validates the data of the redundancy cell region.

The controller may include; an address generation unit suitable for generating first and second physical addresses of the respective normal and redundancy cell regions corresponding to a logical address of the data; and an address mapping unit suitable for mapping the logical address to the first and second physical addresses, and validates or invalidates the data of the normal and redundancy cell regions by validating or invalidating the first and second addresses depending on detection of an error in the data read from the normal cell region.

The controller may further include an error detection and correction unit suitable for detecting and correcting the error in the data.

When detecting an error in the data read from the normal cell region, the address mapping unit may invalidate the first address and validate the second address.

The controller may further copy data corresponding to the validated second address of the redundancy cell region into the normal cell region.

The address mapping unit further map the logical address of the data to a physical address of the copied data in the normal cell region with the second address and validate the physical address of the copied data as the first address of the data, and invalidate the second address.

During a garbage collection operation to the normal cell region, when a region corresponding to the first address is selected as a victim region, the address mapping unit may further invalidate the first address and validate the second address.

The controller may disable the second physical address generated by the address generation unit when a free space of the memory device is less than a reference value.

The normal cell region may include a plurality of multi-level cell memory blocks, and the redundancy cell region may include a plurality of single-level cell memory blocks.

The normal and redundancy cell regions respectively may include first and second memory chips sharing a channel and operative by a single chip enable signal.

Said duplicate programming may be performed through a single transmission operation of the data from the controller to both the normal cell region and the redundancy cell region.

The memory device may be a flash memory.

In accordance with an embodiment of the present invention, an operating method for a memory system includes: programming data in duplicate both into a normal cell region and a redundancy cell region of a memory device of the memory system; detecting an error in the data read from the normal cell region; invalidating the data programmed in the normal cell region; and validating the data programmed in the redundancy cell region.

The programming of the data may include: generating first and second physical addresses of the respective normal and redundancy cell regions corresponding to a logical address of the data; mapping the logical address to the first and second physical addresses; and validating the first address and invalidating the second address.

The invalidating and validating of the data of the normal and redundancy cell regions may be performed by validating or invalidating the first and second addresses depending on detection of an error in the data read from the normal cell region.

The operating method may further include copying data corresponding to the validated second address of the redundancy cell region into the normal cell region.

The operating method may further include: mapping the logical address of the data to a physical address of the copied data in the normal cell region with the second address; validating the physical address of the copied data as the first address of the data; and invalidating the second address.

The operating method may further include performing a garbage collection operation to the normal cell region.

The operation method may further include, when a region corresponding to the first address is selected as a victim region:

invalidating the first address; and validating the second address.

The memory device may be a flash memory.

### BRIEF DESCRIPTION OF THE DRAWINGS

These and other features and advantages of the present invention become apparent from the following detailed description in reference to the accompanying drawings, wherein:

FIG. 1 is a block diagram illustrating a data processing system including a memory system, operatively coupled to a host, according to an embodiment of the present invention.

FIG. 2 is a schematic diagram illustrating a configuration example of a memory device employed in the memory system of FIG. 1.

FIG. 3 is a diagram schematically illustrating a memory cell array of a memory block in the memory device of FIG. 2.

FIG. 4 is a diagram schematically illustrating a 3-D configuration of the memory blocks of the memory device of FIG. 2.

FIG. 5 is a block diagram illustrating a memory system, according to an embodiment of the present invention.

FIGS. 6A to 6C illustrate an address map table of an operation of an address mapping unit shown in FIG. 5.

FIG. 7 is a flowchart illustrating an operation of the memory system of FIG. 5, according to an embodiment of the present invention.

FIG. 8 is a diagram illustrating a memory card system, according to an embodiment of the present invention.

FIG. 9 is a block diagram illustrating a data processing system, according to an embodiment of the present invention.

FIG. 10 is a block diagram illustrating a solid-state drive (SSD), according to an embodiment of the present invention.

FIG. 11 is a block diagram illustrating an embedded multimedia card (eMMC), according to an embodiment of the present invention.

FIG. 12 is a block diagram illustrating a universal flash storage (UFS), according to an embodiment of the present invention.

FIG. 13 is a block diagram illustrating a user system including a memory system, according to an embodiment of the present invention.

### DETAILED DESCRIPTION

Although, various embodiments are described below in more detail with reference to the accompanying drawings, we note that the present invention may, however, be embodied in different other embodiments, and variations thereof should not be construed as being limited only to the embodiments set forth herein. Rather, the described embodiments are provided so that this disclosure will be thorough and complete, and will fully convey the present invention to those skilled in the art to which this invention pertains. Throughout the disclosure, like reference numerals refer to like parts throughout the various figures and embodiments of the present invention.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

The drawings are not necessarily to scale and, in some instances, proportions may have been exaggerated in order to clearly illustrate various features of the embodiments.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present.

The terminology used herein is for the purpose of describing particular embodiments only and is not intended to be limiting of the present invention.

As used herein, singular forms are intended to include the plural forms as well, unless the context clearly indicates otherwise.

It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

Unless otherwise defined, all terms including technical and scientific terms used herein have the same meaning as commonly understood by one of ordinary skill in the art to which the present invention belongs in view of the present disclosure. It will be further understood that terms, such as those defined in commonly used dictionaries, should be interpreted as having a meaning that is consistent with their meaning in the context of the present disclosure and the relevant art and will not be interpreted in an idealized or overly formal sense unless expressly so defined herein.

We further note that in the following description, numerous specific details are set forth in for providing a thorough understanding of the present invention. However, as would be apparent to those skilled in the relevant art, the present invention may be practiced without some or all of these specific details. In other instances, well-known process structures and/or processes have not been described in detail in order not to unnecessarily obscure the present invention.

It is also noted, that in some instances, as would be apparent to those skilled in the relevant art, a feature or element described in connection with one embodiment may be used singly or in combination with other features or elements of another embodiment, unless otherwise specifically indicated.

Hereinafter, the various embodiments of the present invention will be described with reference to the attached drawings.

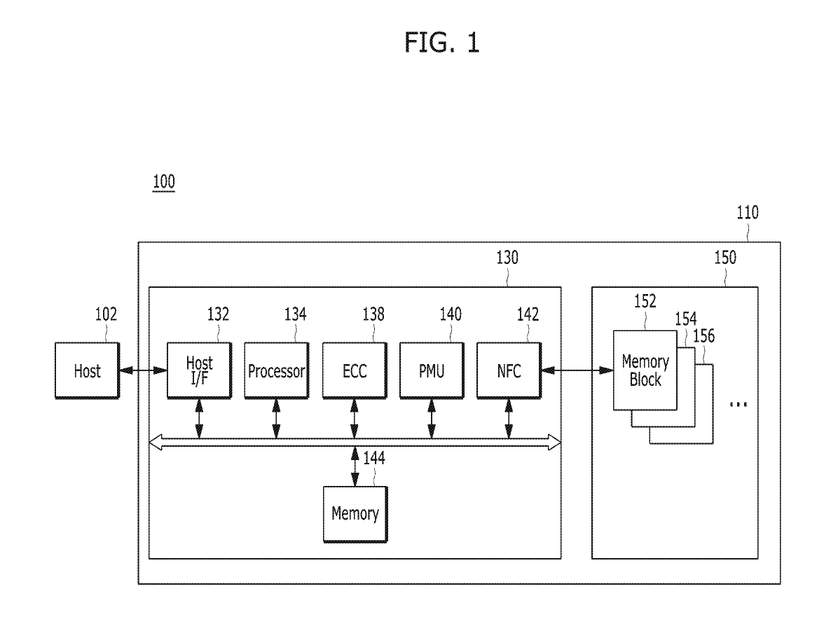

Referring now to FIG. 1, a data processing system 100 including a memory system 110 is provided, according to an embodiment of the present invention.

The data processing system 100 may include a host 102 operatively coupled to the memory system 110.

The host 102 may be or include a portable electronic device such as a mobile phone, an MP3 player and a laptop computer or a non-portable electronic device such as a desktop computer, a game player, a television (TV) and a projector.

The memory system 110 may operate in response to a request received from the host 102. For example, the memory system 110 may store data to be accessed by the host 102 in response to a request received from the host 102. The memory system 110 may be used as a main memory system or an auxiliary memory system of the host 102. The memory system 110 may be implemented with any one of various storage devices, according to the protocol of a host interface to be coupled electrically with the host 102. The memory system 110 may be implemented with any one of various storage devices, such as, for example, a solid state drive (SSD), a multimedia card (MMC), a secure digital (SD) card, a universal serial bus (USB) storage device, a universal flash storage (UFS) device, a compact flash (CF) card, a smart media card (SMC), a personal computer memory card international association (PCMCIA) card and a memory stick. The MMC may include an embedded MMC (eMMC), a reduced size MMC (RS-MMC) and a micro-MMC, and the SD card may include a mini-SD card and a micro-SD card.

The storage devices for the memory system 110 may be implemented with a volatile memory device, such as, a dynamic random access memory (DRAM) and a static random access memory (SRAM) or a nonvolatile memory device such as a read only memory (ROM), a mask ROM (MROM), a programmable ROM (PROM), an erasable programmable ROM (EPROM), an electrically erasable programmable ROM (EEPROM), a ferroelectric random access memory (FRAM), a phase-change RAM (PRAM), a magnetoresistive RAM (MRAM), a resistive RAM (RRAM), and a flash memory. The flash memory may be a NAND or a NOR flash memory and may have a 3-dimensional (3D) stack structure.

The memory system 110 may include a memory device 150 and a controller 130 operatively coupled to the memory device 150 for controlling the storage of data in the memory device 150 and the transfer of stored data from the memory device 150 to the host 102.

The controller 130 and the memory device 150 may be integrated into a single semiconductor device, which may be included in the various types of memory system as exemplified above.

Non-limited application examples of the memory system 110 may include a computer, an Ultra Mobile PC (UMPC), a workstation, a net-book, a Personal Digital Assistant (PDA), a portable computer, a web tablet, a tablet computer, a wireless phone, a mobile phone, a smart phone, an e-book, a Portable Multimedia Player (PMP), a portable game machine, a navigation system, a black box, a digital camera, a Digital Multimedia Broadcasting (DMB) player, a 3-dimensional television, a smart television, a digital audio recorder, a digital audio player, a digital picture recorder, a digital picture player, a digital video recorder, a digital video player, a storage device constituting a data center, a device capable of transmitting/receiving information in a wireless environment, one of various electronic devices constituting a home network, one of various electronic devices constituting a computer network, one of various electronic devices constituting a telematics network, a Radio Frequency Identification (RFID) device, or one of various components constituting a computing system.

The memory device 150 of the memory system 110 may retain stored data when power supply to the device is interrupted. The memory device 150 may store data provided from the host 102 through a write operation, and provide data stored therein to the host 102 through a read operation. The memory device 150 may include a plurality of memory dies each including a plurality of planes each including a plurality of memory blocks 152 to 156. Each of the memory blocks 152 to 156 may include a plurality of pages. Each of the pages may include a plurality of memory cells coupled to a word line (WL) (See FIG. 3). The memory device 150 may be a nonvolatile memory device. For example, the nonvolatile memory device may be a flash memory. The flash memory may have a three-dimensional (3D) stack structure.

The controller 130 may control the memory device 150 in response to a request from the host 102. For example, upon receiving a read request from the host 102, the controller 130 may issue a read command and an address to the memory device for reading the data which are stored in the requested address in the memory device and may provide the data read from the memory device 150, to the host 102. Also, in response to a program request (also referred to as a write request) received from the host 102, the controller 130 may issue a write command, an address and write data and may control the operation of the memory device for storing the write data into the memory device 150. The write data are provided from the host 102 to the memory controller together with the write request. The controller 130 may control one or more operations of the memory device 150 including a read operation, a write operation and an erase operation. The controller 130 may also control one or more background operations of the memory device 150 including, for example, a wear leveling operation, and a garbage operation.

According to the illustrated embodiment of FIG. 1, the controller 130 may include a host interface (I/F) unit 132, a processor 134, an error correction code (ECC) unit 138, a Power Management Unit (PMU) 140, an NAND flash controller (NFC) 142 and a memory 144 operatively coupled to an internal bus.

The host interface unit 132 provides an interface between the host 102 and the controller 130. For example, the host interface unit 132 may receive and process requests, addresses and data provided from the host 102. The host interface unit 132 may also transmit read data from the memory device to the host 102. The host interface unit 132 may communicate with the host 102 through at least one of various well-known interface protocols such as universal serial bus (USB), a multimedia card (MMC), a peripheral component interconnect-express (PCI-E), a serial advanced technology attachment (SATA), a parallel advanced technology attachment (PATA), a small computer system interface (SCSI), a serial attached SCSI (SAS), an enhanced small disk interface (ESDI), and an integrated drive electronics (IDE).

The ECC unit 138 may detect and correct an error contained in the data read from the memory device 150. The ECC unit 138 may perform an error correction decoding process to the data read from the memory device 150 through an ECC code used during the read operation. The ECC unit 138 may not correct error bits when the number of the error bits is greater than a threshold number of correctable error bits, and may output an error correction fail signal indicating failure in correcting the error bits.

The ECC unit 138 may perform an error correction operation using a coded modulation such as a low-density parity check (LDDC) code, a Bose-Chaudhuri-Hocquenghem (BCH) code, a turbo code, a Reed-Solomon (RS) code, a convolution code, a recursive systematic code (RSC), a trellis-coded modulation (TCM), a Block coded modulation (BCM), and so on. The ECC unit 138 may include all circuits, modules, systems or devices for the error correction operation.

The PMU 140 may provide and manage power for the controller 130, that is, power for the component elements included in the controller 130. Any suitable PMU may be employed.

The NFC 142 may serve as a memory interface between the controller 130 and the memory device 150 to allow the controller 130 to control the memory device 150 in response to a request from the host 102. When the memory device 150 is a flash memory or specifically a NAND flash memory, the NFC 142 may generate a control signal for the memory device 150 and process data to be provided to the memory device 150 under the control of the processor 134. The NFC 142 may work as an interface (e.g., a NAND flash interface) for processing a command and data between the controller 130 and the memory device 150. Specifically, the NFC 142 may support data transfer between the controller 130 and the memory device 150. Other well-known memory interfaces may be employed for a different type memory device.

The memory 144 may serve as a working memory of the memory system 110 and the controller 130, and store data for driving the memory system 110 and the controller 130. The controller 130 may control the memory device 150 in response to a request from the host 102. For example, the controller 130 may provide data read from the memory device 150 to the host 102, may store data provided from the host 102 into the memory device 150. When the controller 130 controls the operations of the memory device 150, the memory 144 may store data used by the controller 130 and the memory device 150 for such operations as read operation, write operation, program operation and erase operation. The memory 144 may include a program memory, a data memory, a write buffer, a read buffer, a map buffer, and so forth.

The memory 144 may be implemented with a volatile memory. For example, the memory 144 may be implemented with a static random access memory (SRAM) or a dynamic random access memory (DRAM). The memory 144 may be disposed within or out of the controller 130. FIG. 1 exemplifies the memory 144 disposed within the controller 130. In an embodiment, the memory 144 may be embodied by an external volatile memory having a memory interface transferring data between the memory 144 and the controller 130.

The processor 134 may control an operation of the memory system 110. For example, the processor 134 may control a write operation or a read operation for the memory device 150, in response to a write request or a read request from the host 102. The processor 134 may drive firmware to control an operation of the memory system 110. The firmware may be a flash translation layer (FTL). In an embodiment, the processor 134 may be implemented with a microprocessor. In another embodiment, the processor 134 may be implemented with a central processing unit (CPU).

A management unit (not shown) may be included in the processor 134 for performing a bad block management operation of the memory device 150. For example, the management unit may find bad memory blocks included in the memory device 150, which are in unsatisfactory condition for further use, and perform bad block management on the bad memory blocks. When the memory device 150 is a flash memory, for example, a NAND flash memory, a program failure may occur during the write operation, for example, during the program operation, due to characteristics of a NAND logic function. During the bad block management, the data of the program-failed memory block or the bad memory block may be programmed into a new memory block. Reliable bad block management may reduce deterioration of the utilization efficiency and increase the reliability of the memory device 150.

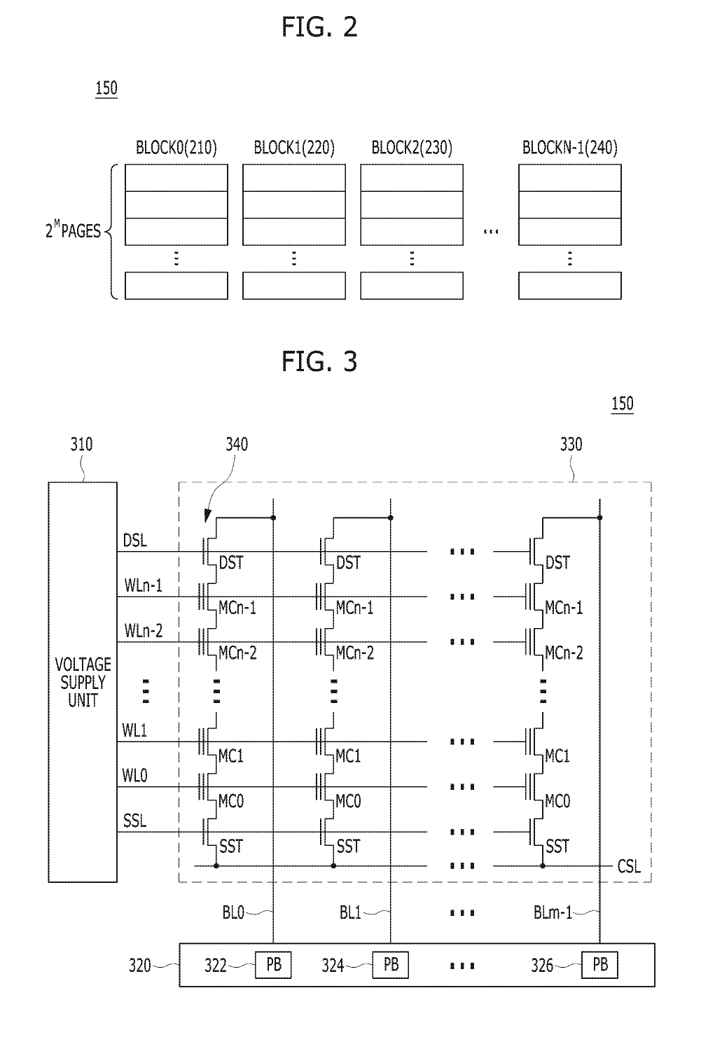

FIG. 2 is a schematic diagram illustrating the memory device 150.

Referring to FIG. 2, the memory device 150 may include a plurality of memory blocks 0 to N−1, and each of the blocks 0 to N−1may include a plurality of pages, for example, 2^{M} pages. The number of memory blocks and the number of pages in each memory block may vary according to design. Memory cells included in the respective memory blocks 0 to N−1 may be one or more of a single level cells (SLC) storing 1-bit data, and multi-level cells (MLC) storing two, three or more bits of data. An SLC memory block may include a plurality of pages which are implemented with memory cells each capable of storing 1-bit data. An MLC memory block may include a plurality of pages which are implemented with memory cells each capable of storing multi-bit data (e.g., two or more-bit data). An MLC memory block including a plurality of pages which are implemented with memory cells that are each capable of storing 3-bit data may be also referred to as a triple level cell (TLC) memory block.

Each of the plurality of memory blocks 210 to 240 may store data provided from the host device 102 during a write operation. Also, each of the plurality of memory bocks may provide stored data to the host 102 during a read operation.

FIG. 3 is a circuit diagram illustrating a memory cell array of the memory block 330 in the memory device 150 of FIG. 2.

Referring to FIG. 3, each memory block 330 of the memory device 150 may include a plurality of cell strings 340 coupled to a plurality of bit lines BL0 to BLm−1. The cell string 340 of each column may include at least one drain select transistor DST and at least one source select transistor SST. A plurality of memory cells or memory cell transistors MC0 to MCn−1 may be coupled in series between the select transistors SST and DST. The respective memory cells MC0 to MCn−1 may be constructed by multi-level cells (MLC) each of which stores data information of a plurality of bits. Each of the cell strings 340 may be electrically coupled to a corresponding bit line among the plurality of bit lines BL0 to BLm−1. For reference, in FIG. 3, ‘DSL’ may denote a drain select line, and ‘SSL’ may denote a source select line, and ‘CSL’ may denote a common source line.

While FIG. 3 shows, as an example, the memory block 330 which is constructed by NAND flash memory cells, it is to be noted that the memory block 330 of the memory device 150 is not limited to a NAND flash memory and may be implemented by a NOR flash memory, a hybrid flash memory in which at least two kinds of memory cells are combined or a one-NAND flash memory in which a controller is built in a memory chip. The memory device 150 may be a flash memory device including a conductive floating gate as a charge storage layer or a charge trap flash (CTF) memory device including an insulation layer as a charge storage layer.

The memory device 150 may include a voltage supply unit 310 which provides word line voltages including a program voltage, a read voltage and a pass voltage to the word lines according to an operation mode and provides other voltage to the well regions, for example, bulk, of memory cells. The voltage generation operation of the voltage supply unit 310 may be controlled by a control circuit (not illustrated). Under the control of the control circuit, the voltage supply unit 310 may select one of the memory blocks (or sectors) of the memory cell array, select one of the word lines of the selected memory block, and provide the word line voltages to the selected word line and the unselected word lines.

A read/write circuit 320 of the memory device 150 is controlled by the control circuit, and may operate as a sense amplifier or a write driver according to an operation mode. For example, in the case of a verify/normal read operation, the read/write circuit 320 may operate as a sense amplifier for reading data from the memory cell array. During a program operation, the read/write circuit 320 may operate as a write driver for driving bit lines according to data to be stored in the memory cell array. During a program operation, the read/write circuit 320 may receive data to be written in the memory cell array, from a buffer (not shown), and may drive the bit lines according to inputted data. The read/write circuit 320 may include a plurality of page buffers 322 to 326 respectively corresponding to columns (or bit lines) or column pairs (or bit line pairs), and each of the page buffers 322 to 326 may include a plurality of latches (not illustrated).

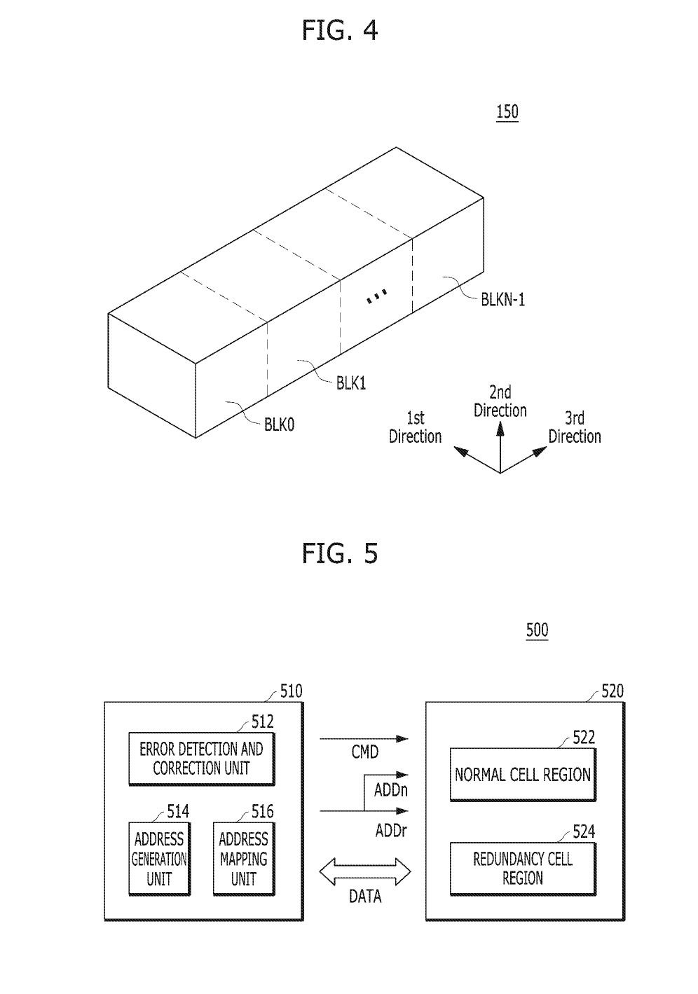

FIG. 4 is a schematic diagram illustrating a structure of the memory device 150.

The memory device 150 may be embodied by a 2D or 3D memory device. Specifically, as illustrated in FIG. 4, the memory device 150 may be embodied by a nonvolatile memory device having a 3D stack structure. When the memory device 150 has a 3D structure, the memory device 150 may include a plurality of memory blocks BLK0 to BLKN−1. FIG. 4 illustrates the memory blocks 152 to 156 of the memory device 150, and each of the memory blocks 152 to 156 may have a 3D structure (or vertical structure).

The memory blocks BLK0 to BLKN−1 of the memory device 150 may include a plurality of NAND strings (such as the cell string 340 of FIG. 3), each NAND string extending in the second direction shown in FIG. 4. The plurality of NAND strings may be spaced apart at regular intervals in the first direction and the third direction shown in FIG. 4. As shown in the cell sting 340 of FIG. 3, a plurality of NAND strings may be coupled to at least one drain select line DSL coupled to the gate of each drain select transistor DST, at least one source select line SSL coupled to the gate of each source select transistor SST, a plurality of word lines WL1 to WLn−1, at least one dummy word line WL0 and a common source line CSL.

Namely, each of the memory blocks BLK0 to BLKN−1 may be coupled to a plurality of bit lines, a plurality of drain select lines, a plurality of source select lines, a plurality of word lines, a plurality of dummy word lines and a plurality of common source lines, and accordingly, may include a plurality of NAND strings. Also, in the respective memory blocks BLK0 to BLKN−1, a plurality of NAND strings may be coupled to one bit line, and a plurality of transistors may be realized in one NAND string. A drain select transistor of each NAND string may be coupled to a corresponding bit line, and a source select transistor of each NAND string may be coupled to the common source line. (See FIG. 3).

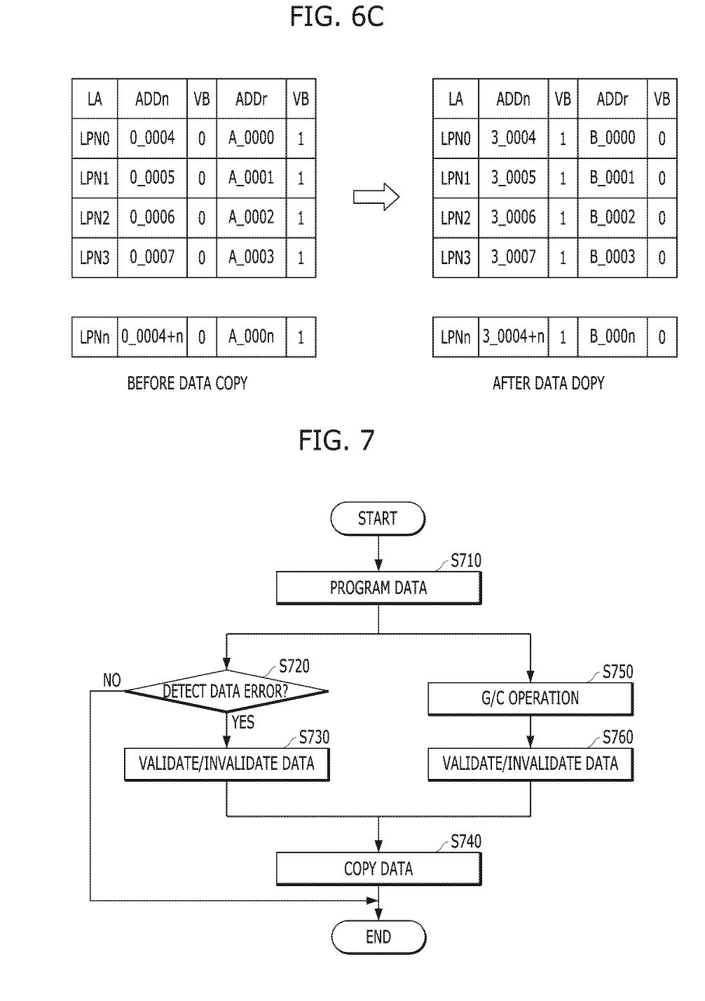

Described hereafter is an operation of programming data to the memory device 150 and detecting and managing an error of the programmed data in the memory system 110 of FIG. 1 in accordance with an embodiment of the present invention with reference to FIGS. 5 and 7.

FIG. 5 is a block diagram illustrating a memory system 500 according to an embodiment of the present invention.

Referring FIG. 5, the memory system 500 includes a controller 510 and a memory device 520. In an embodiment, the memory device 520 may be a nonvolatile memory device, for example, a NAND flash memory device, however, the present disclosure is not limited thereto.

The controller 510 may control the memory device 520 in response to a request from a host (not shown), in the same manner as that of the controller 130 shown in FIG. 1. That is, the controller 510 may provide data read from the memory device 520 to the host, and store data provided from the host in the memory device 520. For this, the controller 510 may control program, read, erase operations, etc. of the memory device 520. Therefore, the controller 510 may include the similar components as the controller 130 shown in FIG. 1.

The controller 510 may further program the same data to a normal cell region 522 as well as to a redundancy cell region 524 of the memory device 520. In response to a single request from the host, different memory blocks of normal and redundancy cell regions 522 and 524 may be designated in the memory device 520, and the same data may be stored in both of the designated memory blocks. Each of the normal and redundancy cell regions 522 and 524 may include a plurality of MLC memory blocks and a plurality of SLC memory blocks.

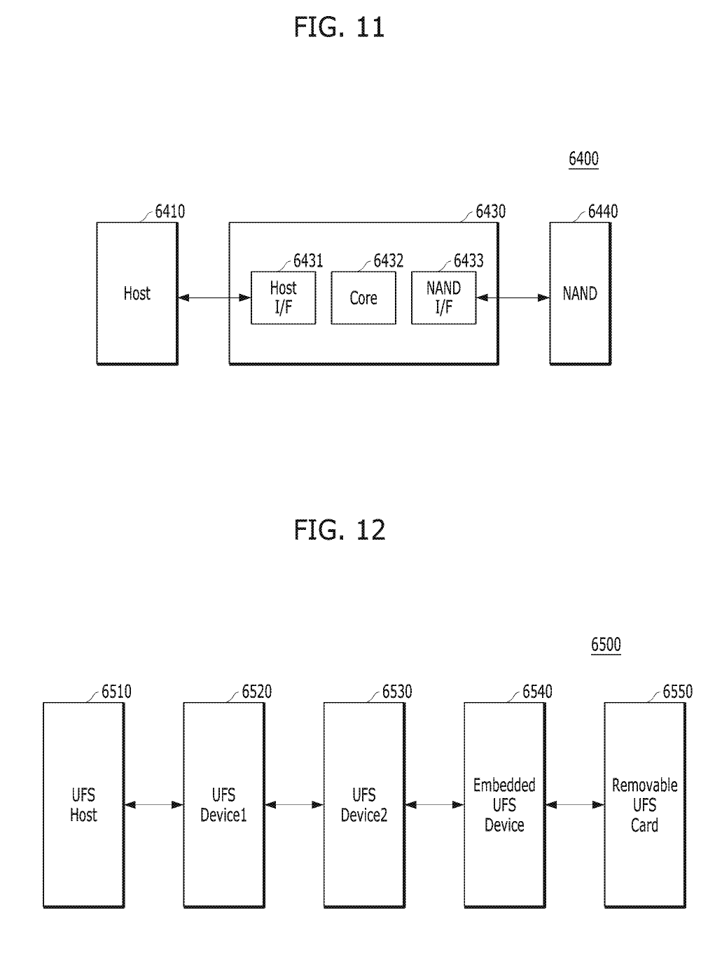

The memory device 520 may have a Redundant Array of Independent Disks (RAID) structure in which a plurality of memory chips are stacked. The normal and redundancy cell regions 522 and 524 may include memory chips which share a channel and are enabled by an identical chip enable signal. The memory system having the RAID structure will be described in more detail with reference to FIG. 11.

For example, the memory device 520 may have a Double Die Package (DDP) structure in which two memory chips to be driven by a single chip enable signal are packaged. The two memory chips of the DDP structure may be included in the normal and redundancy cell regions 522 and 524, respectively. The controller 510 may simultaneously enable the memory chips included in each of the normal and redundancy cell regions 522 and 524 and transmit addresses corresponding to the respective memory chips on a distributed cycle. The controller 510 may transmit data through a shared channel, and simultaneously program the data into enabled memory chips of both the normal and redundancy cell regions 522 and 524 through a single data transmission operation.

In order to program (that is, update) new data to a region (e.g., a page) storing existing data, in the memory device 520 of a NAND flash type, the controller 510 should erase the existing data from the region. However, if an erase operation is performed each time a data update operation is performed, the operating speed and or efficiency of the memory system 500 may be deteriorated. Therefore, the controller 510 invalidates the region storing the existing data, and programs the new data to a new region which is free. Furthermore, in order to reflect the invalidation of the current data and the program of the new data into an address map table, the controller 510 maps location information for the invalidated region data and for the newly programmed region in the address map table. That is, the firmware such as the FTL included in the controller 510 performs the mapping operation of mapping a logical address LA of the programmed data to a physical address PA of the memory device 520. The FTL may write and manage the address map table so as to assist in such an address mapping operation.

As shown in FIG. 5, the controller 510 may also include an address generation unit 514 and an address mapping unit 516.

The address generation unit 514, in response to a logical address LA and corresponding data received from a host, may generate a physical address PA indicating a region in the memory device 520 where the received data may be programmed. For a single logical address LA of data, the address generation unit 514 may generate first and second physical addresses PA. The first physical address may be a normal address ADDn that designates a memory location in the normal cell region 522. The second physical address may be a redundancy address ADDr that designates a memory location in the redundancy cell region 524.

The address mapping unit 516 may map the generated normal and redundancy addresses ADDn and ADDr and the corresponding logical address LA in the address map table. The address mapping unit 516 may also validate or invalidate each of the mapped normal and redundancy addresses ADDn and ADDr.

The address generation unit 514 may not generate a physical address PA according to a logical address LA mapped to a validated address in the address map table of the address mapping unit 516.

The controller 510 may access the normal cell region 522 according to the logical address LA mapped to a validated normal address ADDn in the address map table of the address mapping unit 516.

As shown in FIG. 5, the controller 510 may further include an error detection and correction unit 512. The error detection and correction unit 512 may detect and correct an error of data read from the memory device 520. The operation of the error detection and correction unit 512 may be the same as that of the ECC unit 138 described with reference to FIG. 1.

When, as a result of the detection operation of the error detection and correction unit 512, an error is detected from data programmed to the normal cell region 522, data programmed in the redundancy cell region 524 may be used in lieu of the error-detected data of the normal cell region 522 in the memory device 520. For example, when an error of bits greater than correctable error bits is detected from data programmed to the normal cell region 522, data programmed in the redundancy cell regions 524 may be used. In order to use the data programmed in the redundancy cell region 524, the address mapping unit 516 will invalidate the normal address ADDn of the error-detected data in the normal cell region 522 and validate the redundancy address ADDr of the data programmed in the redundancy cell region 524. In this manner, the controller 510 can protect the data from error-corruption without having to perform a data copy operation as required in a typical read reclaim operation.

The operation of the controller 510 may be applied to a garbage collection operation. The controller 510 may check how much free space exists in the memory device 520, and may perform a garbage collection operation when the free space is less than a predetermined reference value. A garbage collection operation may secure free space by selecting a victim region, collecting any valid data of the victim region into a different memory region, and then erasing the victim region to make it a free region. A region is selected to be a victim region when it is storing a lot of invalid data. For example, a victim region may be defined as a region storing invalid data equal to or more than a threshold value.

In this regard, in the case where the controller 510 performs a garbage collection operation to the normal cell region 522, the garbage collection operation may be completed by invalidating the normal addresses ADDn of valid data included in the normal cell region 522 selected as the victim region and by validating the redundancy addresses ADDr of the valid data included in the redundancy cell region 524 corresponding to the victim region through the address mapping unit 516. Therefore, the controller 510 may perform the garbage collection operation without performing an operation of collecting and copying valid data, thus making it possible to reduce overhead in the operation of the memory system.

After checking the free space of the memory device 520, the controller 510 may disable one of the first and second physical addresses PA generated by the address generation unit 514 if the free space is less than a predetermined reference value or if defective space of the memory device 520 is equal to the predetermined reference value or more. For example, only the first physical address PA representing a memory location of the normal cell region 522 may be mapped to a logical address LA in order to program data provided from the host.

Through continued operations, if a lot of data of the normal cell region 522 are replaced with data of the redundancy cell region 524, the controller 510 may copy data of the redundancy cell region 524 into the normal cell region 522 in a single batch operation and may then use the data copied into the normal cell region 522. For example, in the case where the controller 510 performs a garbage collection operation for the redundancy cell region 524, valid data corresponding to the validated redundancy addresses ADDr among valid data included in the redundancy cell region 524 selected as a victim region may be copied together to the normal cell region 522. In this case, the address mapping unit 516 may validate addresses corresponding to the data copied into the normal cell region 522 as the normal addresses ADDn of the copied data, and invalidate the redundancy addresses ADDr of the copied-out data of the redundancy cell region 524. Therefore, the data copied to the normal cell region 524 may be used, and the copied-out data of the redundancy cell region 524 may be stored as a spare.

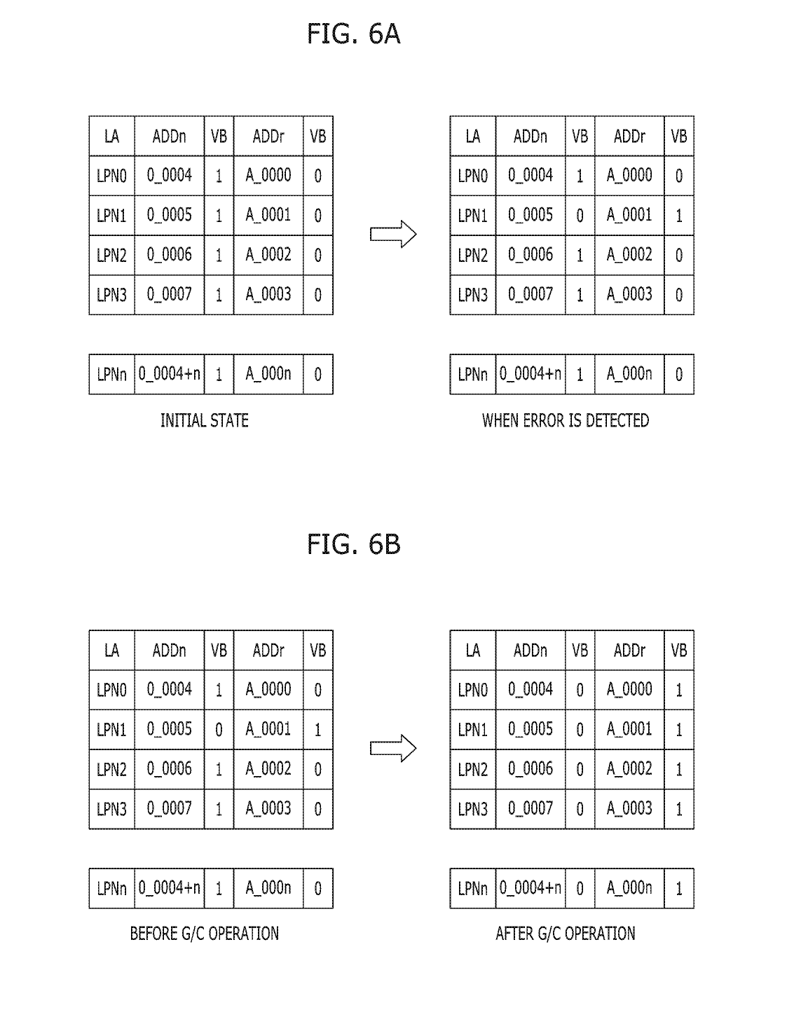

FIGS. 6A to 6C are the address map table illustrating an operation of an address mapping unit shown in FIG. 5.

Referring to the address map table of an ‘INITIAL STATE’ of FIG. 6A, the controller 510 has stored data requested to be programmed from the host in the normal and redundancy cell regions 522 and 524 of the memory device 520. That is, data corresponding to the logical addresses LPN0 to LPNn are programmed to the normal cell region 522 at normal addresses 0_0004 to 0_00004+n and also simultaneously programmed to the redundancy cell region 524 at redundancy addresses A_0000 to A_000n. In this regard, the address mapping unit 516 may map the logical addresses LA to the normal and redundancy addresses ADDRn and ADDRr and enable and manage valid bits VB corresponding to the normal addresses ADDRn.

Thereafter, based on the enabled valid bits VB, in response to a request from the host for the logical addresses LPN0 to LPNn, data corresponding to the normal addresses 0_0004 to 0_00004+n is accessed. For example, on a read request for the logical address LPN1, data stored in the normal cell region 522 is read at the normal address 0_0005.

The error detection and correction unit 512 may detect an error of data read from the normal cell region 522 during a normal read operation. Alternatively, the controller 510 may select a target region from the normal cell region 522 with reference to the number of times of write and read operations performed therein, and the error detection and correction unit 512 may detect an error of data read from the target region during the idle time of the memory device 520. Operations related to this are not the gist of the present disclosure; therefore, detailed description thereof will be omitted.

If an error of data stored in the normal cell region 522 is detected by the error detection and correction unit 512, the address mapping unit 516 may reset the mapping relation of the address map table based on the detected error.

Referring to the address map table of ‘WHEN ERROR IS DETECTED’ of FIG. 6A, an error has been detected from the data of the normal address 0_0005 by the error detection and correction unit 512. Thereby, the address mapping unit 516 may disable and invalidate the valid bit VB corresponding to the normal address 0_0005 and, instead, enable the valid bit VB corresponding to the associated redundancy address A_0001. Subsequently, based on the enabled valid bits VB, in response to a request from the host for the logical address LPN1, data of the redundancy address A_0001 may be accessed.

FIG. 6B is a block diagram showing the address map table reset according to a garbage collection (G/C) operation. FIG. 6B illustrates the states of the address map table before and after the garbage collection (G/C) operation for the normal cell region 522.

Referring to the address map table of ‘BEFORE G/C OPERATION’ of FIG. 6B, the data corresponding to the normal address 0_0005 in the normal cell region 522 has been invalidated by detection of an error or the like and replaced with data corresponding to the redundancy address A_0001 in the redundancy cell region 524. When a G/C operation is performed for the normal cell region 522 and a region corresponding to the normal address 0_0004 to 0_0004+n is selected as a victim region, the G/C operation may be completed by simply invalidating corresponding valid bits VB without performing a substantial data copy and collection operation.

That is, valid data of the normal addresses 0_0004, 0_0006 to 0_00004+n may be collected based on the enabled valid bits VB in the normal cell region 522 and replaced with the valid data corresponding redundancy addresses A_0000, A_0002 to A_000n in the redundancy cell region 524. Therefore, the valid bits VB of the normal addresses 0_0004, 0_0006 to 0_00004+n may be disabled, and the valid bits VB of the redundancy addresses A_0000, A_0002 to A_000n may be additionally enabled. In this regard, the relation of the normal and redundancy addresses 0_0005 and A_0001 corresponding to the already replaced data, that is, corresponding to the logical address LPN1, may be maintained without change.

Therefore, referring to the address map table of ‘AFTER G/C OPERATION’ of FIG. 6B, according to the G/C operation to the normal cell region 522, all of the normal addresses 0_0004 to 0_00004+n corresponding to the logical addresses LPN0 to LPNn are invalidated (VB: 0), and all of the redundancy addresses A_0000 to A_000n are validated (VB: 1) so that the whole data of the normal cell region 522 are replaced with the same data stored in the redundancy cell region 524.

FIG. 6C is a block diagram showing the address map table reset according to an operation of copying the data stored in the redundancy cell region 524.

As described above, over time, if a lot of data of the normal cell region 522 are replaced with the data of the redundancy cell region 524, the data of the redundancy cell region 524 may be copied to the normal cell region 522 in a batch and used. For example, the controller 510 may also copy, to the normal cell region 522, data collected in the redundancy cell region 524 during performing a garbage collection operation, thereby maintaining the same data in both of the normal and redundancy cell regions 522 and 524.

Referring to the address map table of ‘BEFORE DATA COPY’ of FIG. 6C, all data of the normal cell region 522 corresponding to the logical addresses LPN0 to LPNn have been invalidated and replaced with data of the redundancy cell region 524. In this regard, if a G/C operation is performed for the redundancy cell region 524 and a region corresponding to the redundancy addresses A_000 to A_00n is selected as a victim region, the corresponding data may be copied not only to the redundancy region 524 but also to the normal cell region 522.

Referring to the address map table of ‘AFTER DATA COPY’ of FIG. 6B, data have been copied to the normal cell region 522 corresponding to normal addresses 3_0000 to 3_0000n and the redundancy cell region 524 corresponding to redundancy addresses B_0000 to B_000n. In this case, the address mapping unit 516 may validate all of the valid bits VB of the normal addresses 3_0000 to 3_0000n and invalidate all of the valid bits VB of the redundancy addresses B_0000 to B_000n to manage the addresses. FIG. 6C illustrates the address map table reset during a data copy operation according to a G/C operation, but the present disclosure is not limited to this. That is, data corresponding to valid bits VB enabled in the redundancy cell region 524 may be collected and copied to only the normal cell region 522. In this case, there is no change in the redundancy addresses ADDRn of the data, and only corresponding valid bits VB are disabled.

FIG. 7 is a flowchart illustrating an operation of the memory system 500. Referring to FIG. 7, a method of operating the memory system 500 in accordance with an embodiment includes a step S710 of programming data, a step S720 of detecting a program error, a step S730 of validating/invalidating data, and step S740 of copying data. Furthermore, in accordance with an embodiment, the method may further include a step S750 of performing a garbage collection (G/C) operation, and a step S760 of validating/invalidating data.

At step S710, the controller 510 may program data to the memory device 520 in response to a request from the host. While programming data to the normal cell region 522, the controller 510 may also simultaneously program the data to the redundancy cell region 524.

In response to addresses of the data inputted from the host, the address generation unit 514 may generate first and second addresses (i.e., the normal and redundancy addresses ADDn and ADDr) of the normal and redundancy cell regions 522 and 524. The address mapping unit 516 may manage the first and second addresses by respectively validating and invalidating the first and second addresses.

At step S720, the error detection and correction unit 512 may detect an error from the data programmed in the normal cell region 522. If an error is detected from the data by the error detection and correction unit 512, the controller 510 may invalidate the data programmed in the normal cell region 522 and validate the data programmed in the redundancy cell region 524. The address mapping unit 516 may invalidate the first address (i.e., the normal address ADDn) corresponding to the data and validate the second address (i.e., the redundancy address ADDr).

At step S740, the controller 510 may copy data of the validated second address from the redundancy cell region 524 to the normal cell region 522. In this case, the address mapping unit 516 may validate the address corresponding to the copied normal cell region as the first address (i.e., the normal address ADDn), and thus invalidate the second address.

At step S750, the controller 510 may perform a garbage collection (G/C) operation to the normal cell region 522. The controller 510 may check free space of the normal cell region 522 and perform the G/C operation when the free space is less than a reference value.

At step S760, the controller 510 may invalidate data in a selected victim region of the normal cell region 522 through the G/C operation of step S750, and validate data programmed to the redundancy cell region 524. In this regard, the address mapping unit 516 may invalidate the first address corresponding to the data and validate the second address. Data corresponding to the validated second address may be copied from the redundancy cell region 524 to the normal cell region 522 through step S740.

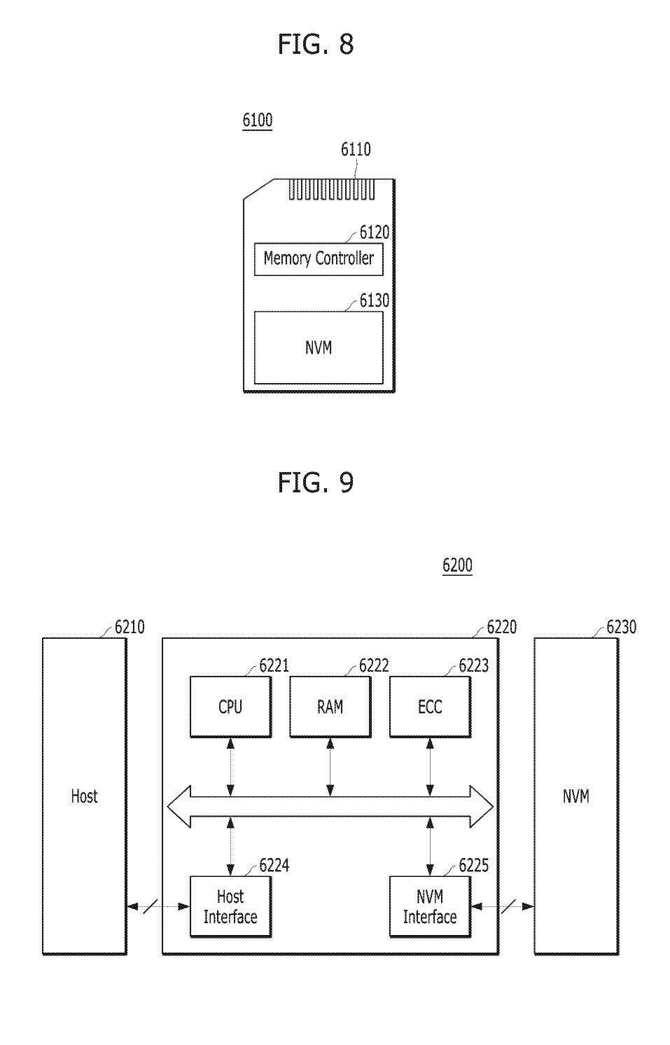

Hereafter, a data processing system and various electronic devices including the memory system 110 are described in more detail with reference to FIGS. 8 to 13. FIGS. 8 to 13 are diagrams schematically illustrating application examples of the data processing system of FIG. 1.

FIG. 8 is a diagram schematically illustrating another example of the data processing system including the memory system in accordance with an embodiment. Specifically, FIG. 8 schematically illustrates a memory card system including a memory system, in accordance with an embodiment.

Referring to FIG. 8, the memory card system 6100 may include a memory controller 6120, a memory device 6130, and a connector 6110.

The memory controller 6120 may be connected to the memory device 6130 embodied by a nonvolatile memory, and may access the memory device 6130. For example, the memory controller 6120 may control read, write, erase and background operations of the memory device 6130. The memory controller 6120 may provide an interface between the memory device 6130 and a host, and drive firmware for controlling the memory device 6130. That is, the memory controller 6120 may correspond to the controller 130 of the memory system 110 described with reference to FIG. 1, and the memory device 6130 may correspond to the memory device 150 of the memory system 110 described with reference to FIG. 1.

Therefore, the memory controller 6120 may include components such as a RAM, a processing unit, a host interface, a memory interface and an error correction unit as illustrated in FIG. 1.

The memory controller 6120 may communicate with an external device, for example, the host 102 described above with reference to FIG. 1, through the connector 6110. For example, as described above with reference to FIG. 1, the memory controller 6120 may be configured to communicate with the external device through at least one of various communication protocols such as universal serial bus (USB), multimedia card (MMC), embedded MMC (eMMC), peripheral component interconnection (PCI), PCI express (PCIe), Advanced Technology Attachment (ATA), Serial-ATA, Parallel-ATA, small computer system interface (SCSI), enhanced small disk interface (EDSI), Integrated Drive Electronics (IDE), Firewire, universal flash storage (UFS), WIFI and Bluetooth. Accordingly, the memory system and the data processing system may be applied to wired/wireless electronic appliances, in particular, a mobile electronic appliance.

The memory device 6130 may be implemented by a nonvolatile memory. For example, the memory device 6130 may be implemented by various nonvolatile memory devices such as an erasable and programmable ROM (EPROM), an electrically erasable and programmable ROM (EEPROM), a NAND flash memory, a NOR flash memory, a phase-change RAM (PRAM), a resistive RAM (ReRAM), a ferroelectric RAM (FRAM) and a spin torque transfer magnetic RAM (STT-RAM).

The memory controller 6120 and the memory device 6130 may be integrated into a single semiconductor device. For example, the memory controller 6120 and the memory device 6130 may construct a solid-state driver (SSD) by being integrated into a single semiconductor device. Also, the memory controller 6120 and the memory device 6130 may construct a memory card such as a PC card (PCMCIA: Personal Computer Memory Card International Association), a compact flash (CF) card, a smart media card (e.g., SM and SMC), a memory stick, a multimedia card (e.g., MMC, RS-MMC, MMCmicro and eMMC), an SD card (e.g., SD, miniSD, microSD and SDHC) and a universal flash storage (UFS).

FIG. 9 is a diagram schematically illustrating another example of a data processing system 6200 including the memory system according to an embodiment of the present invention.

Referring to FIG. 9, the data processing system 6200 may include a memory device 6230 which may be implemented by at least one nonvolatile memory (NVM) and a memory controller 6220 which controls the memory device 6230. The data processing system 6200 illustrated in FIG. 9 may serve as a storage medium such as a memory card (CF, SD, micro-SD or the like) or USB device, as described with reference to FIG. 1. The memory device 6230 may correspond to the memory device 150 in the memory system 110 illustrated in FIG. 1, and the memory controller 6220 may correspond to the controller 130 in the memory system 110 illustrated in FIG. 1.

The memory controller 6220 may control a read, write or erase operation on the memory device 6230 in response to a request of the host 6210, and the memory controller 6220 may include one or more CPUs 6221, a buffer memory such as RAM 6222, an ECC circuit 6223, a host interface 6224 and a memory interface such as an NVM interface 6225.

The CPU 6221 may control overall operations on the memory device 6230, for example, read, write, file system management and bad page management operations. The RAM 6222 may be operated according to control of the CPU 6221, and used as a work memory, buffer memory or cache memory. When the RAM 6222 is used as a work memory, data processed by the CPU 6221 may be temporarily stored in the RAM 6222. When the RAM 6222 is used as a buffer memory, the RAM 6222 may be used for buffering data transmitted to the memory device 6230 from the host 6210 or transmitted to the host 6210 from the memory device 6230. When the RAM 6222 is used as a cache memory, the RAM 6222 may assist the low-speed memory device 6230 to operate at high speed.

The ECC circuit 6223 may correspond to the ECC unit 138 of the controller 130 illustrated in FIG. 1. As described with reference to FIG. 1, the ECC circuit 6223 may generate an ECC (Error Correction Code) for correcting a fail bit or error bit of data provided from the memory device 6230. The ECC circuit 6223 may perform error correction encoding on data provided to the memory device 6230, thereby forming data with a parity bit. The parity bit may be stored in the memory device 6230. The ECC circuit 6223 may perform error correction decoding on data outputted from the memory device 6230. At this time, the ECC circuit 6223 may correct an error using the parity bit. For example, as described with reference to FIG. 1, the ECC circuit 6223 may correct an error using the LDPC code, BCH code, turbo code, Reed-Solomon code, convolution code, RSC or coded modulation such as TCM or BCM.

The memory controller 6220 may transmit/receive data to/from the host 6210 through the host interface 6224, and transmit/receive data to/from the memory device 6230 through the NVM interface 6225. The host interface 6224 may be connected to the host 6210 through a PATA bus, SATA bus, SCSI, USB, PCIe or NAND interface. The memory controller 6220 may have a wireless communication function with a mobile communication protocol such as WiFi or LTE (Long Term Evolution). The memory controller 6220 may be connected to an external device, for example, the host 6210 or another external device, and then transmit/receive data to/from the external device. In particular, as the memory controller 6220 is configured to communicate with the external device through one or more of various communication protocols, the memory system and the data processing system in accordance with an embodiment may be applied to wired/wireless electronic devices or particularly a mobile electronic device.

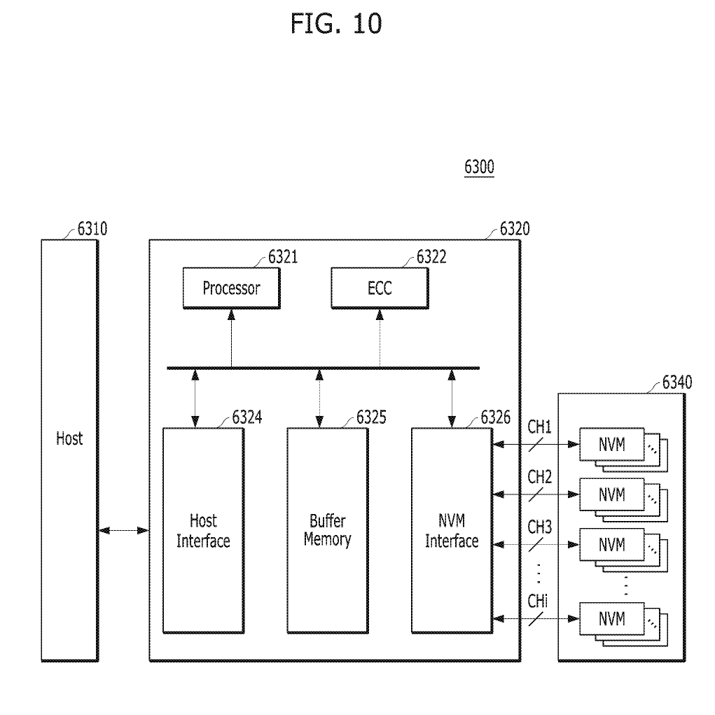

FIG. 10 is a diagram schematically illustrating another example of the data processing system including the memory system in accordance with an embodiment. Specifically, FIG. 10 schematically illustrates an SSD.

Referring to FIG. 10, the SSD 6300 may include a controller 6320 and a memory device 6340 including a plurality of nonvolatile memories. The controller 6320 may correspond to the controller 130 in the memory system 110 of FIG. 1, and the memory device 6340 may correspond to the memory device 150 in the memory system 110 of FIG. 1.

The controller 6320 may be connected to the memory device 6340 through a plurality of channels CH1 to CHi. The controller 6320 may include at least one processor 6321, a buffer memory 6325, an ECC circuit 6322, a host interface 6324, and a memory interface such as a nonvolatile memory interface 6326.

The buffer memory 6325 may temporarily store data provided from the host 6310 or data provided from a plurality of flash memories NVM included in the memory device 6340, or temporarily store meta data of the plurality of flash memories NVM, for example, map data including a mapping table. The buffer memory 6325 may be embodied by volatile memories such as DRAM, SDRAM, DDR SDRAM, LPDDR SDRAM and GRAM or nonvolatile memories such as FRAM, ReRAM, STT-MRAM and PRAM. For convenience of description, FIG. 10 illustrates that the buffer memory 6325 exists in the controller 6320. However, the buffer memory 6325 may exist outside the controller 6320.

The ECC circuit 6322 may calculate an ECC value of data to be programmed to the memory device 6340 during a program operation, perform an error correction operation on data read from the memory device 6340 based on the ECC value during a read operation, and perform an error correction operation on data recovered from the memory device 6340 during a failed data recovery operation.

The host interface 6324 may provide an interface function with an external device, for example, the host 6310, and the nonvolatile memory interface 6326 may provide an interface function with the memory device 6340 connected through the plurality of channels.

Furthermore, a plurality of SSDs 6300 to which the memory system 110 of FIG. 1 is applied may be provided to embody a data processing system, for example, RAID (Redundant Array of Independent Disks) system. At this time, the RAID system may include the plurality of SSDs 6300 and a RAID controller for controlling the plurality of SSDs 6300. When the RAID controller performs a program operation in response to a write command provided from the host 6310, the RAID controller may select one or more memory system or SSDs 6300 according to a plurality of RAID levels, that is, RAID level information of the write command provided from the host 6310 in the SSDs 6300, and output data corresponding to the write command to the selected SSDs 6300. Furthermore, when the RAID controller performs a read operation in response to a read command provided from the host 6310, the RAID controller may select one or more memory systems or SSDs 6300 according to a plurality of RAID levels, that is, RAID level information of the read command provided from the host 6310 in the SSDs 6300, and provide data read from the selected SSDs 6300 to the host 6310.

FIG. 11 is a diagram schematically illustrating another example of the data processing system including the memory system in accordance with an embodiment. Specifically, FIG. 11 schematically illustrates an embedded Multi-Media Card (eMMC).

Referring to FIG. 11, the eMMC 6400 may include a controller 6430 and a memory device 6440 embodied by one or more NAND flash memories. The controller 6430 may correspond to the controller 130 in the memory system 110 of FIG. 1, and the memory device 6440 may correspond to the memory device 150 in the memory system 110 of FIG. 1.

The controller 6430 may be connected with the memory device 6440 through a plurality of channels. The controller 6430 may include a host interface 6431, at least one core 6432, and a memory interface, for example, a NAND interface 6433.

The core 6432 may control overall operations of the eMMC 6400, the host interface 6431 may provide an interface function between the controller 6430 and the host 6410, and the NAND interface 6433 may provide an interface function between the memory device 6440 and the controller 6430. For example, the host interface 6431 may serve as a parallel interface, for example, MMC interface as described with reference to FIG. 1. Furthermore, the host interface 6431 may serve as a serial interface, for example, UHS ((Ultra High Speed)-I/UHS-II) interface.

FIG. 12 is a diagram schematically illustrating another example of the data processing system including the memory system, in accordance with an embodiment. Specifically, FIG. 12 schematically illustrates a universal flash storage (UFS) system 6500.

Referring to FIG. 12, the UFS system 6500 may include a UFS host 6510, a plurality of UFS devices 6520 and 6530, an embedded UFS device 6540, and a removable UFS card 6550. The UFS host 6510 may be an application processor of wired/wireless electronic appliances, in particular, a mobile electronic appliance.

The UFS host 6510, the UFS devices 6520 and 6530, the embedded UFS device 6540 and the removable UFS card 6550 may respectively communicate with external devices, that is, wired/wireless electronic appliances, in particular, a mobile electronic appliance, through a UFS protocol. The UFS devices 6520 and 6530, the embedded UFS device 6540 and the removable UFS card 6550 may be implemented as the memory system 110 described above with reference to FIG. 1, in particular, as the memory card system 6100 described above with reference to FIG. 8. The embedded UFS device 6540 and the removable UFS card 6550 may communicate through another protocol other than the UFS protocol. For example, the embedded UFS device 6540 and the removable UFS card 6550 may communicate through various card protocols such as, but not limited to, USB flash drives (UFDs), a multimedia card (MMC), secure digital (SD), mini SD and Micro SD.

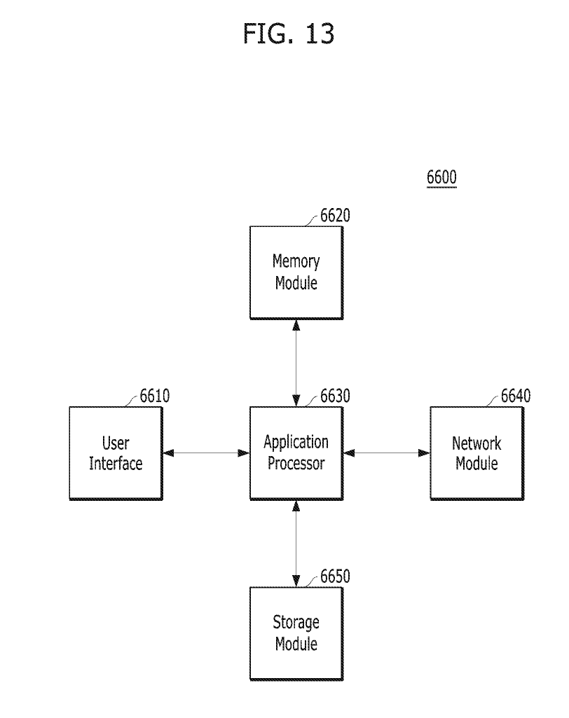

FIG. 13 is a diagram schematically illustrating another example of the data processing system including the memory system in accordance with an embodiment. Specifically, FIG. 13 schematically illustrates a user system 6600.

Referring to FIG. 13, the user system 6600 may include a user interface 6610, a memory module 6620, an application processor 6630, a network module 6640, and a storage module 6650.

The application processor 6630 may drive components included in the user system 6600, for example, an OS, and include controllers, interfaces and a graphic engine which control the components included in the user system 6600. The application processor 6630 may be provided as SoC (System-on-Chip).

The memory module 6620 may be used as a main memory, work memory, buffer memory or cache memory of the user system 6600. The memory module 6620 may include a volatile RAM such as DRAM, SDRAM, DDR SDRAM, DDR2 SDRAM, DDR3 SDRAM, LPDDR SDARM, LPDDR3 SDRAM or LPDDR3 SDRAM or a nonvolatile RAM such as PRAM, ReRAM, MRAM or FRAM. For example, the application processor 6630 and the memory module 6620 may be packaged and mounted, based on POP (Package on Package).

The network module 6640 may communicate with external devices. For example, the network module 6640 may support not only wired communications but also various wireless communications such as code division multiple access (CDMA), global system for mobile communication (GSM), wideband CDMA (WCDMA), CDMA-2000, time division multiple access (TDMA), long term evolution (LTE), worldwide interoperability for microwave access (Wimax), wireless local area network (WLAN), ultra-wideband (UWB), Bluetooth, wireless display (WI-DI), and so on, and may thereby communicate with wired/wireless electronic devices or particularly mobile electronic devices. Therefore, the memory system and the data processing system can be applied to wired/wireless electronic devices. The network module 6640 may be included in the application processor 6630.

The storage module 6650 may store data, for example, data provided from the application processor 6630, and then transmit the stored data to the application processor 6630. The storage module 6650 may be embodied by nonvolatile semiconductor memory devices such as a phase-change RAM (PRAM), a magnetic RAM (MRAM), a resistive RAM (ReRAM), a NAND flash, NOR flash and 3D NAND flash, and provided as a removable storage medium such as a memory card or external drive of the user system 6600. That is, the storage module 6650 may correspond to the memory system 110 described with reference to FIG. 1. Furthermore, the storage module 6650 may be embodied by SSD, eMMC and UFS described with reference to FIGS. 10 to 12.

The user interface 6610 may include interfaces for inputting data or commands to the application processor 6630 or outputting data to an external device. For example, the user interface 6610 user input interfaces such as a keyboard, a keypad, a button, a touch panel, a touch screen, a touch pad, a touch ball, a camera, a microphone, a gyroscope sensor, a vibration sensor and a piezoelectric element, and user output interfaces such as a liquid crystal display (LCD), an organic light emitting diode (OLED) display device, an active matrix OLED (AMOLED) display device, an LED, a speaker and a motor.

Furthermore, when the memory system 110 of FIG. 1 is applied to a mobile electronic device of the user system 6600, the application processor 6630 may control overall operations of the mobile electronic device, and the network module 6640 may serve as a communication module for controlling wired/wireless communication with an external device. The user interface 6610 may display data processed by the application processor 6630 on a display/touch module of the mobile electronic device, or support a function of receiving data from the touch panel.

In a memory system and an operating method for the memory system in accordance with embodiments, data may be programmed to a plurality of regions of a memory device, and, when an error occurs in data of any one of the regions, data of the other regions may substitute for the data in which the error occurs. Therefore, data may be protected from an error by managing only information (addresses) corresponding to the data without performing a substantial operation of correcting the error or copying the data.

Furthermore, the operation of the present disclosure may also be applied to an operation such as a garbage collection operation in such a way that valid data of a victim region may be replaced with data that has been stored together therewith. Therefore, an operation of copying, that is, reading and programming data, may be omitted when valid data are collected, thereby reducing overhead of a memory system in operation of securing free space of a memory device.

Although various embodiments have been described for illustrative purposes, it will be apparent to those skilled in the art that various other embodiments, and changes or modifications thereof may be made without departing from the spirit and scope of the invention as defined in the following claims.

What is claimed is:

1. A memory system comprising:
a memory device including a normal cell region and a redundancy cell region; and
a controller suitable for programming data in duplicate in both the normal and the redundancy cell regions,
wherein when detecting an error in the data read from the normal cell region, the controller invalidates the data of the normal cell region and validates the data of the redundancy cell region.

2. The memory system of claim 1, wherein the controller comprises:
an address generation unit suitable for generating first and second physical addresses of the respective normal and redundancy cell regions corresponding to a logical address of the data; and
an address mapping unit suitable for mapping the logical address to the first and second physical addresses, and validates or invalidates the data of the normal and redundancy cell regions by validating or invalidating the first and second addresses depending on detection of an error in the data read from the normal cell region.

3. The memory system of claim 2, wherein the controller further comprises an error detection and correction unit suitable for detecting and correcting the error in the data.

4. The memory system of claim 3, wherein, when detecting an error in the data read from the normal cell region, the address mapping unit invalidates the first address and validates the second address.

5. The memory system of claim 4, wherein the controller further copies data corresponding to the validated second address of the redundancy cell region into the normal cell region.

6. The memory system of claim 5, wherein the address mapping unit further maps the logical address of the data to a physical address of the copied data in the normal cell region with the second address and validates the physical address of the copied data as the first address of the data, and invalidates the second address.

7. The memory system of claim 2, wherein, during a garbage collection operation to the normal cell region, when a region corresponding to the first address is selected as a victim region, the address mapping unit further invalidates the first address and validates the second address.

8. The memory system of claim 2, wherein the controller disables the second physical address generated by the address generation unit when a free space of the memory device is less than a reference value.

9. The memory system of claim 1,
wherein the normal cell region includes a plurality of multi-level cell memory blocks, and
wherein the redundancy cell region includes a plurality of single-level cell memory blocks.

10. The memory system of claim 1, wherein the normal and redundancy cell regions respectively includes first and second memory chips sharing a channel and operative by a single chip enable signal.

11. The memory system of claim 10, wherein said duplicate programming is performed through a single transmission operation of the data from the controller to both the normal cell region and the redundancy cell region.

12. The memory device of claim 1, wherein the memory device is a flash memory.

13. An operating method for a memory system, the operating method comprising:
programming data in duplicate both into a normal cell region and a redundancy cell region of a memory device of the memory system;
detecting an error in the data read from the normal cell region;
invalidating the data programmed in the normal cell region; and
validating the data programmed in the redundancy cell region.

14. The operating method of claim 13,
wherein the programming of the data comprises:
generating first and second physical addresses of the respective normal and redundancy cell regions corresponding to a logical address of the data;
mapping the logical address to the first and second physical addresses; and
validating the first address and invalidating the second address.

15. The operating method of claim 14, wherein the invalidating and validating of the data of the normal and redundancy cell regions is performed by validating or invalidating the first and second addresses depending on detection of an error in the data read from the normal cell region.

16. The operating method of claim 15, further comprising copying data corresponding to the validated second address of the redundancy cell region into the normal cell region.

17. The operating method of claim 16, further comprising:
mapping the logical address of the data to a physical address of the copied data in the normal cell region with the second address;
validating the physical address of the copied data as the first address of the data; and
invalidating the second address.

18. The operating method of claim 14, further comprising performing a garbage collection operation to the normal cell region.

19. The operating method of claim 18, further comprising, when a region corresponding to the first address is selected as a victim region:
invalidating the first address; and
validating the second address.

20. The operating method of claim 13, wherein the memory device is a flash memory.
